(19) United States
(12) Patent Application Publication
(10) Pub. No.: US 2026/0293304 A1
(43) Pub. Date: Sep. 24, 2026

(54) SEMICONDUCTOR DEVICE AND METHOD OF FABRICATING THE SAME

(71) Applicant: Samsung Electronics Co., Ltd., Suwon-si (KR)

(72) Inventors: Hongshin Kim, Suwon-si (KR); Wooseok Park, Suwon-si (KR); Youngjin Yang, Suwon-si (KR)

(21) Appl. No.: 19/327,099

(22) Filed: Sep. 12, 2025

(30) Foreign Application Priority Data
Mar. 21, 2025 (KR) 10-2025-0036818

(51) Int. Cl. H10D 84/85; H10D 84/01

(52) U.S. Cl. CPC H10D 84/852; H10D 84/0167; H10D 84/017; H10D 84/0188

(57) ABSTRACT

An example semiconductor device comprises an active pattern on a substrate, a first channel structure and a second channel structure spaced apart from each other on the active pattern, a gate electrode on the first channel structure and the second channel structure and a separation structure provided between the first channel structure and the second channel structure. Each of the first channel structure and the second channel structure includes a plurality of semiconductor patterns. A level of an upper surface of the separation structure is higher than that of an upper surface of an uppermost semiconductor pattern among the plurality of semiconductor patterns. The gate electrode provided between the plurality of semiconductor patterns is in contact with the separation structure.

### CROSS-REFERENCE TO RELATED APPLICATION

This patent application claims priority under 35 U.S.C. § 119 to Korean Patent Application No. 10-2025-0036818, filed on Mar. 21, 2025, in the Korean Intellectual Property Office, the entire contents of which are hereby incorporated by reference.

### BACKGROUND

A semiconductor device may include an integrated circuit comprising metal-oxide-semiconductor field-effect transistors (MOS-FETs). To meet an increasing demand for a semiconductor device with a small pattern size and a reduced design rule, the MOS-FETs has been scaled down. The scale-down of the MOS-FETs may lead to deterioration in operation characteristics of the semiconductor device. Overcoming technical hurdles associated with the scale-down of the semiconductor device and providing the semiconductor device with high performance are desired.

### SUMMARY

The present disclosure relates to a semiconductor device with improved electrical and reliability characteristics.

In general, according to some aspects, a semiconductor device may include an active pattern on a substrate, a first channel structure and a second channel structure spaced apart from each other on the active pattern, a gate electrode on the first channel structure and the second channel structure and a separation structure provided between the first channel structure and the second channel structure, wherein each of the first channel structure and the second channel structure includes a plurality of semiconductor patterns, wherein a level of an upper surface of the separation structure is higher than that of an upper surface of an uppermost semiconductor pattern among the plurality of semiconductor patterns, and wherein the gate electrode provided between the plurality of semiconductor patterns is in contact with the separation structure.

In general, according to some aspects, a semiconductor device may include a substrate comprising an active pattern, a device isolation layer defining the active pattern, a first channel structure and a second channel structure spaced apart from each other on the active pattern, a gate electrode on the first channel structure and the second channel structure, a gate insulating layer provided between the gate electrode and the first channel structure and between the gate electrode and the second channel structure and a separation structure provided between the first channel structure and the second channel structure, wherein each of the first channel structure and the second channel structure includes a plurality of semiconductor patterns having four surfaces, a level of an upper surface of the separation structure is higher than that of an upper surface of an uppermost semiconductor pattern among the plurality of semiconductor patterns, the gate insulating layer surrounds the four surfaces of each of the plurality of semiconductor patterns, and a portion of a side surface of the separation structure is exposed from the gate insulating layer.

In general, according to some aspects, a semiconductor device may include a substrate comprising a first active pattern and a second active pattern defined by a device isolation layer, a first channel structure on the first active pattern and a second channel structure on the second active pattern, source/drain patterns connected to the first channel structure and the second channel structure, a first gate electrode on the first channel structure and a second gate electrode on the second channel structure, a gate insulating layer provided between the first gate electrode and the first channel structure and between the second gate electrode and the second channel structure, and a separation structure provided between the first channel structure and the second channel structure, wherein each of the first channel structure and the second channel structure includes a plurality of semiconductor patterns having four surfaces, the gate insulating layer surrounds the four surfaces of each of the plurality of semiconductor patterns, a level of an upper surface of the separation structure is higher than that of an upper surface of an uppermost semiconductor pattern among the plurality of semiconductor patterns, and a portion of a side surface of the separation structure is in contact with the gate insulating layer, and the rest of the side surface of the separation structure is in contact with the first and second gate electrodes in a horizontal point of view.

In general, according to some aspects, a method of manufacturing a semiconductor device may include forming a first channel structure and a second channel structure comprising a plurality of semiconductor patterns on a substrate, forming a gate insulating layer on the semiconductor patterns, forming a separation structure including a core structure between the first channel structure and the second channel structure, and forming a gate electrode on the gate insulating layer, wherein forming the plurality of the semiconductor patterns includes forming first semiconductor layers and second semiconductor layers alternately stacked on the substrate, wherein forming the gate insulating layer includes forming the gate insulating layer to surround four surfaces of the semiconductor patterns, forming the separation structure includes forming a photoresist pattern covering the plurality of semiconductor patterns on the substrate, etching the photoresist pattern to form a hole, filling the hole with an insulating material, and etching an upper portion of the insulating material.

In general, according to some aspects, forming the upper portion of the insulating material may include performing the etching process so that a level of an upper surface of the insulating material remains above a level of an upper surface of a semiconductor pattern provided on the uppermost of the plurality of semiconductor patterns.

In general, according to some aspects, forming the separation structure may further comprise etching the upper portion of the insulating material to form a core structure, removing the photoresist pattern, and forming a cladding structure surrounding the core structure.

In general, according to some aspects, forming the gate electrode may include forming the gate electrode until a level of an upper surface of the gate electrode is equal to a level of an upper surface of the separation structure.

In general, according to some aspects, the method of manufacturing a semiconductor device may further comprise forming source/drain patterns connected to the first channel structure and the second channel structure before forming the separation structure.

### BRIEF DESCRIPTION OF THE DRAWINGS

FIG. 1 is a plan view of illustrating an example of a semiconductor device.

FIG. 2A is an example cross-sectional view taken along line A-A′ of FIG. 1.

FIG. 2B is an example cross-sectional view taken along line B-B′ of FIG. 1.

FIG. 2C is an example cross-sectional view taken along line C-C′ of FIG. 1.

FIG. 2D is an example cross-sectional view taken along line D-D′ of FIG. 1.

FIG. 3 is an example enlarged view illustrating a portion ‘CU’ of FIG. 2A.

FIG. 4 is an example enlarged view illustrating a portion ‘CU’of FIG. 2A.

FIG. 5 is an example cross-sectional view taken along line A-A′ of FIG. 1.

FIGS. 6A, 6B, 7A, 7B, 7C, 8A, 8B, 8C, 8D, 9A, 9B, 9C, 9D, 10A, 10B, 10C, 11A, 11B, 12A, 12B, 12C, 13A, 13B, 13C, 13D, 14A, 14B, 14C, 14D, 15A, 15B, 16A, 16B, 16C, and 16D are cross-sectional views illustrating an example of a process of fabricating a semiconductor device.

### DETAILED DESCRIPTION

Example implementations will now be described more fully with reference to the accompanying drawings, in which example implementations are shown.

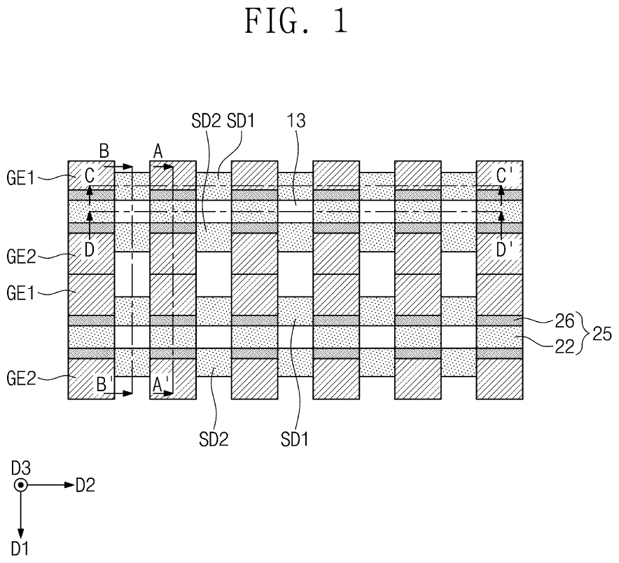

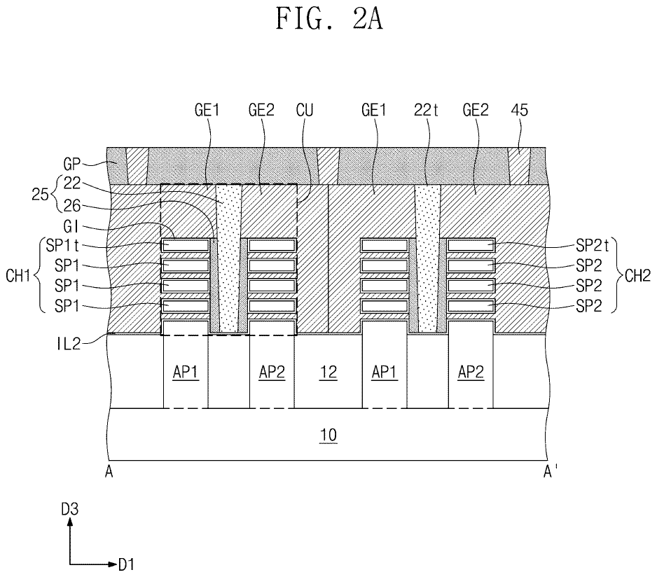

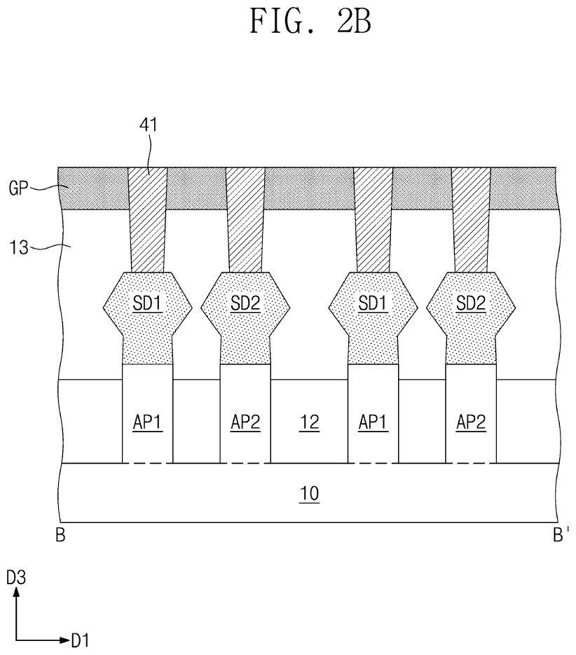

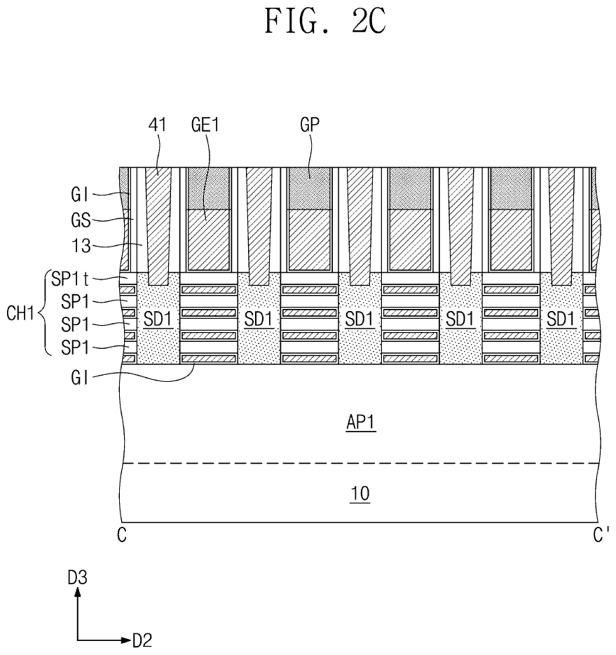

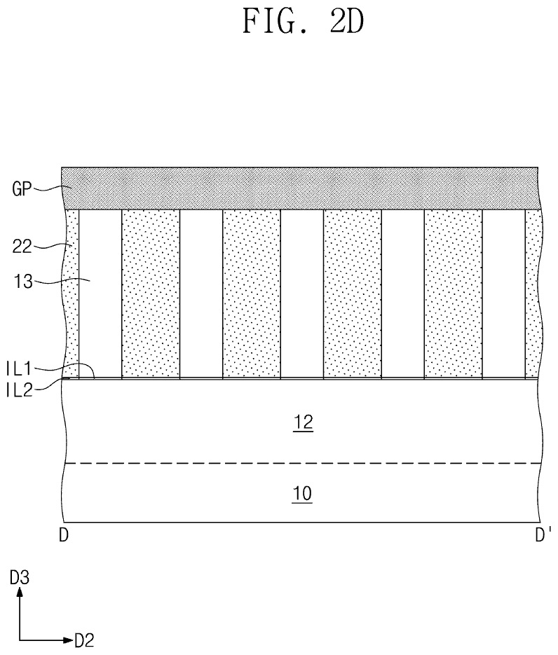

FIG. 1 is a plan view illustrating an example of a semiconductor device. FIG. 2A is an example cross-sectional view taken along line A-A′ of FIG. 1. FIG. 2B is an example cross-sectional view taken along line B-B′ of FIG. 1. FIG. 2C is an example cross-sectional view taken along line C-C′ of FIG. 1. FIG. 2D is an example cross-sectional view taken along line D-D′ of FIG. 1.

Referring to FIGS. 1 to 2D, a semiconductor device may include a substrate 10. The substrate 10 may have a form of a plate extending along a plane defined by a first direction D1 and a second direction D2.

In this specification, the first direction D1 is defined as a direction parallel to an upper surface of the substrate 10. The second direction D2 is defined as a direction parallel to the upper surface of the substrate 10 and perpendicular to the first direction D1. A third direction D3 is defined as a direction perpendicular to the upper surface of the substrate 10.

The substrate 10 may be a semiconductor substrate, an insulating substrate, SOI (Silicon On Insulator) substrate, or GOI (Germanium On Insulator) substrate. The semiconductor substrate may include, for example, silicon (Si), germanium (Gi), silicon-germanium (SiGe), GaP, or GaAs.

Logic transistors constituting a logic circuit may be provided on the substrate 10. The substrate 10 may include a first active pattern AP1 and a second active pattern AP2. Each of the first active pattern AP1 and the second active pattern AP2 may be extended in the second direction D2. The first active pattern AP1 and the second active pattern AP2 may be sequentially arranged in the first direction D1. The first active pattern AP1 and the second active pattern AP2 may be spaced apart from each other in the first direction D1. The first active pattern AP1 and the second active pattern AP2 may be adjacent to each other in the first direction D1. The first active pattern AP1 and the second active pattern AP2 may be an upper portion of the substrate 10 protruding in the third direction D3.

Device isolation layers 12 may be provided in the substrate 10. The device isolation layers 12 may be arranged in the first direction D1. The device isolation layers 12 may be provided between the first active pattern AP1 and the second active pattern AP2. That is, the device isolation layers 12 may define the first active pattern AP1 and the second active pattern AP2. The device isolation layers 12 may include an insulating material. For example, the device isolation layers 12 may include silicon oxide.

A first insulating layer IL1 covering the device isolation layers 12 may be provided. A second insulating layer IL2 covering an upper surface of the first active pattern AP1 and an upper surface of the second active pattern AP2 may be provided. The first insulating layer IL1 and the second insulating layer IL2 may include, for example, an insulating material.

First channel structures CH1 may be provided to overlap with the first active pattern AP1 in the third direction D3. Second channel structures CH2 may be provided to overlap with the second active pattern AP2 in the third direction D3.

The channel structures CH1 and CH2, which are overlapped with the active patterns AP1 and AP2 in the third direction D3, may be arranged in the second direction D2. For example, as shown in FIG. 2C, the first channel structures CH1 overlapping with the first active pattern AP1 in the third direction D3 may be spaced apart from each other in the second direction D2.

Each of the first channel structures CH1 may include first semiconductor patterns SP1 arranged in the third direction D3. The first semiconductor patterns SP1 may be spaced apart in the third direction D3. Each of the second channel structures CH2 may include second semiconductor patterns SP2 arranged in the third direction D3. The second semiconductor patterns SP2 may be spaced apart in the third direction D3. The number of the semiconductor patterns SP1 and SP2 in each of the channel structure CH1 and CH2 is not limited to that in the illustrated example.

In some implementations, the first and second semiconductor patterns SP1 and SP2 may include silicon (Si). For example, the first and second semiconductor patterns SP1 and SP2 may include crystalline silicon.

A separation structure 25 may be provided between the first channel structure CH1 and the second channel structure CH2 and between a first gate electrode GE1 and a second gate electrode GE2. The separation structure 25 may be extended in the second direction D2. A plurality of separation structures 25 may be provided along the second direction D2. A level of an upper surface of the separation structure 25 may be higher than the level of upper surfaces of the uppermost semiconductor patterns SP1t and SP2t. Therefore, the first gate electrode GE1 and the second gate electrode GE2 may be separated from each other. A level of a lower surface of the separation structure 25 may be lower than a level of the upper surface of the first active pattern AP1 and that of the upper surface of the second active pattern AP2.

The separation structure 25 may include a core structure 22 and a cladding structure 26 surrounding the core structure 22. A level of an upper surface 22t of the core structure 22 may be higher than the levels of the upper surfaces of the uppermost semiconductor patterns SP1t and SP2t.

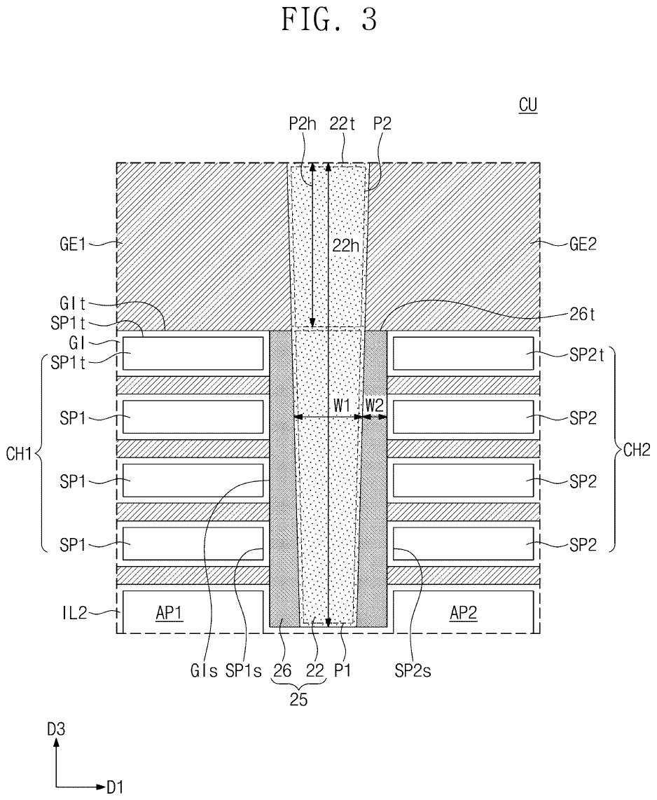

The core structure 22 and the cladding structure 26 may include an insulating material. The core structure 22 and the cladding structure 26 may comprise the same or different materials. For example, the core structure 22 and the cladding structure 26 may include at least one of silicon oxide, silicon nitride, or silicon carbonitride. The description of the separation structure 25 will be described in more detail in FIG. 3.

A first source/drain pattern SD1 may be provided on the first active pattern AP1. A second source/drain pattern SD2 may be provided on the second active pattern AP2. The first source/drain pattern SD1 may overlap with the first active pattern AP1 in the third direction D3. The second source/drain pattern SD2 may overlap with the second active pattern AP2 in the third direction D3. As shown in FIG. 1, the separation structure 25 may be spaced apart from the first source/drain patterns SD1 and the second source/drain pattern SD2.

The first source/drain pattern SD1 may be disposed between the first channel structures CH1, which are adjacent to each other in the second direction D2. The second source/drain pattern SD2 may be disposed between the second channel structures CH2, which are adjacent to each other in the second direction D2. The first source/drain pattern SD1 may be connected to the first semiconductor patterns SP1 of the first channel structures CH1. The second source/drain pattern SD2 may be connected to the second semiconductor patterns SP2 of the second channel structures CH2.

Each of the first and second source/drain patterns SD1 and SD2 may be an epitaxial pattern, which is formed by a selective epitaxial growth process. Each of the first and second source/drain patterns SD1 and SD2 may include, for example, silicon (Si) or silicon-germanium (SiGe).

Each of the first and second source/drain patterns SD1 and SD2 may include impurities. The first source/drain pattern SD1 and the second source/drain pattern SD2 may be doped to have the same conductivity type. As an example, the conductivity type of the first and source/drain patterns SD1 and SD2 may be a P-type. As an example, the conductivity type of the first and second source/drain patterns SD1 and SD2 may be N-type.

In some implementations, the first source/drain pattern SD1 and the second source/drain pattern SD2 may be doped to have different conductivity types from each other. The first source/drain pattern SD1 may be doped to have a first conductivity type, and the second source/drain pattern SD2 may be doped to have a second conductivity type different from the first conductivity type. As an example, the first conductivity type may be P type, and the second conductivity type may be an N type. As an example, the first conductivity type may be N-type, and the second conductivity type may be P-type.

A First gate electrode GE1 may be provided to overlap with the first active pattern AP1 in the third direction D3. The first gate electrode GE1 may be overlapped with the first channel structures CH1 in the third direction D3. A second gate electrode GE2 may be provided to overlap with the second active pattern AP2 in the third direction D3. The second gate electrode GE2 may be overlapped with the second channel structures CH2 in the third direction D3.

The first gate electrode GE1 may be provided between the first source/drain patterns SD1, which are adjacent to each other in the second direction D2. The second gate electrode GE2 may be provided between the second source/drain patterns SD2, which are adjacent to each other in the second direction D2. The first and second gate electrodes GE1 and GE2 and the first and second semiconductor patterns SP1 and SP2 may constitute a three-dimensional field effect transistor (e.g., MBCFET or GAAFET).

A gate insulating layer GI may be provided on the first gate electrode GE1 and the second gate electrode GE2. The gate insulating layer GI may separate the first gate electrode GE1 from the first semiconductor patterns SP1 and the second gate electrode GE2 from the second semiconductor patterns SP2. Based on a line extending in the third direction D3, one end of the gate insulating layer GI may be aligned with one end of the first and second gate electrodes GE1 and GE2. The gate insulating layer GI may include an insulating material. As an example, the gate insulating layer GI may include silicon oxide, silicon oxynitride, and/or a high dielectric constant material. Herein, the high dielectric constant material may be a material having a higher dielectric constant than silicon oxide.

Gate spacers GS may be provided on both sidewalls of the gate electrodes GE1 and GE2. The gate spacers GS may include an insulating material.

A gate capping pattern GP may be provided. The gate capping pattern GP may be provided on the first gate electrode GE1 and the second gate electrode GE2. The gate capping pattern GP may cover the first gate electrode GE1 and the second gate electrode GE2. The gate capping pattern GP may include an insulating material. As an example, the gate capping pattern GP may include silicon nitride.

An interlayer insulating layer 13 may be provided on the device isolation layers 12. The interlayer insulating layer 13 may cover the first source/drain pattern SD1 and the second source/drain pattern SD2. As shown in FIG. 2D, a plurality of separation structures 25 may be provided in the interlayer insulating layer 13 in the second direction D2. The interlayer insulating layer 13 may include an insulating material. As an example, the interlayer insulating layer 13 may include silicon oxide.

Active contacts 41 may be provided. A plurality of active contacts 41 may be provided in the first direction D1. The active contacts 41 may penetrate the gate capping pattern GP and the interlayer insulating layer 13 to connect to the first source/drain pattern SD1 or the second source/drain pattern SD2. The active contacts 41 may include a conductive material. For example, the active contacts 41 may include a metallic material.

Gate contacts 45 may be provided. The gate contacts 45 may be connected to the gate electrodes GE1 and GE2 through the gate capping pattern GP. The gate contacts 45 may include a conductive material. For example, the gate contacts 45 may include a metallic material.

FIG. 3 is an example enlarged view illustrating a portion ‘CU’of FIG. 2A.

Referring to FIGS. 2A and 3, a portion of a side surface of the separation structure 25 may be exposed from the gate insulating layer GI. Specifically, a portion of a side surface of the cladding structure 26 may be exposed from the gate insulating layer GI.

From a vertical perspective, the first gate electrode GE1 provided between the plurality of the first semiconductor patterns SP1 and the second gate electrode GE2 provided between the plurality of the second semiconductor patterns SP2 may be in contact with the separation structure 25. The first gate electrode GE1 may be closer to the separation structure 25 than a side surface SP1s of the first semiconductor patterns SP1, which are the side surface closest to the separation structure 25 among the side surfaces of the first semiconductor pattern SP1. The second gate electrode GE2 may be closer to the separation structure 25 than a side surface SP2s of the second semiconductor patterns SP2, which are the side surface closest to the separation structure 25 among the side surfaces of the second semiconductor patterns SP2.

The gate insulating layer GI may surround the four surfaces of the first semiconductor patterns SP1. The gate insulating layer GI may surround the four surfaces of the second semiconductor patterns SP2. A portion GIs of the gate insulating layer GI surrounding the semiconductor patterns SP1 and SP2 may be in contact with the separation structure 25.

From a vertical perspective, the portion GIs of the gate insulating layer GI that are in contact with the separation structure 25 may overlap with the gate electrodes GE1 and GE2. From a horizontal perspective, a portion of the side surface of the separation structure 25 may be in contact with the gate insulating layer GI, and the rest of the side surface of the separation structure 25 may be in contact with the gate electrodes GE1 and GE2.

From a horizontal perspective, the cladding structure 26 may be provided between the gate insulating layer GI and the core structure 22 and between the gate electrodes GE1 and GE2 and the core structure 22.

The core structure 22 may include a first portion P1 and a second portion P2 on the first portion P1. The second portion P2 may have a shape protruding from the cladding structure 26. That is, the second portion P2 may be located farther from the substrate 10 than the first portion P1. The height P2h of the second portion P2 may be 10% to 45% of the height 22h of the core structure 22. As an example, the height P2h of the second portion P2 may be 5 nm to 40 nm.

The core structure 22 may have a first width W1 in the first direction D1. The first width W1 may increase in the third direction D3 away from the substrate 10. The cladding structure 26 may have a second width W2 in the first direction D1. The second width W2 may decrease in the third direction D3 away from the substrate 10. The second width W2 may be smaller than the first width W1. As an example, the first width W1 may be 10 nm to 40 nm. As an example, the second width W2 may be 2 nm and 10 nm.

A level of an upper surface 22t of the core structure 22 may be higher than that of an upper surface 26t of the cladding structure 26. A level of an upper surface GIt of the gate insulating layer GI surrounding the uppermost semiconductor patterns SP1t and SP2t may be the same as the level of the upper surface 26t of the cladding structure 26.

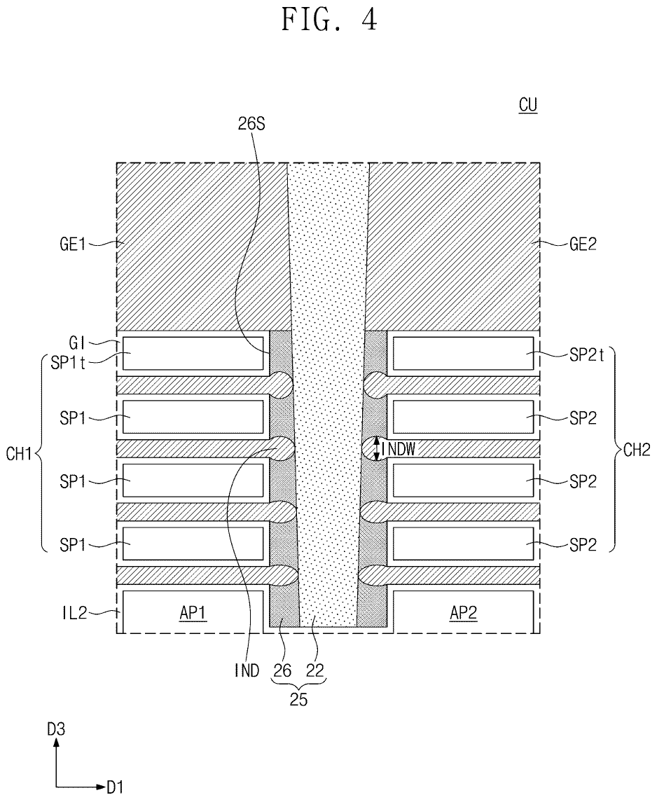

FIG. 4 is an example enlarged view illustrating a portion ‘CU’ of FIG. 2A.

Referring to FIG. 4, a separation structure 25 may include a plurality of indent regions IND. Specifically, a side surface 26S of the cladding structure 26 may have a plurality of indent regions IND. The shape of the indent regions IND is not limited as illustrated.

The first gate electrode GE1 and the second gate electrode GE2 may fill each of the indent regions IND. As an example, a width of each of the indent regions INDW may be 2 nm to 10 nm.

As the separation structure 25 includes the indent regions IND, the areas occupied by the first gate electrode GE1 and the second gate electrode GE2 may increase, thereby further increasing the channel controllability of the first gate electrode GE1 and the second gate electrode GE2.

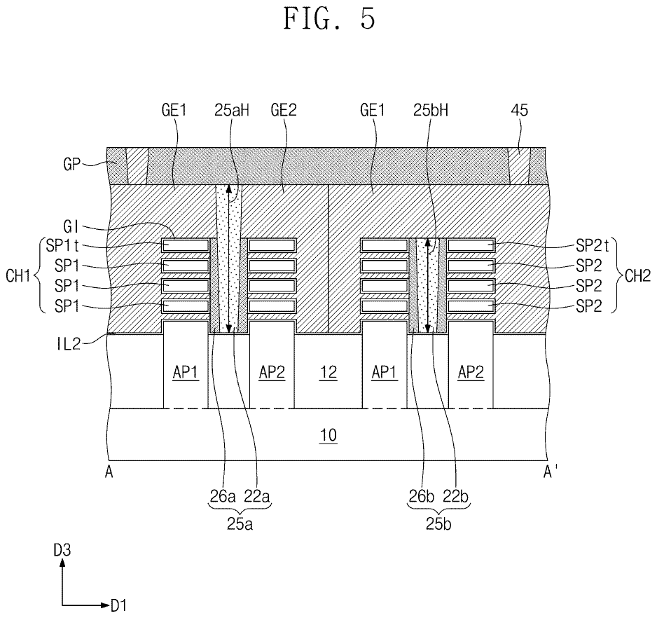

FIG. 5 is an example cross-sectional view taken along line A-A′ of FIG. 1.

Referring to FIG. 5, a semiconductor device may include a first separation structure 25a and a second separation structure 25b. The first separation structure 25a may include a first core structure 22a and a first cladding structure 26a surrounding the first core structure 22a. The second separation structure 25b may include a second core structure 22b and a second cladding structure 26b surrounding the second core structure 22b.

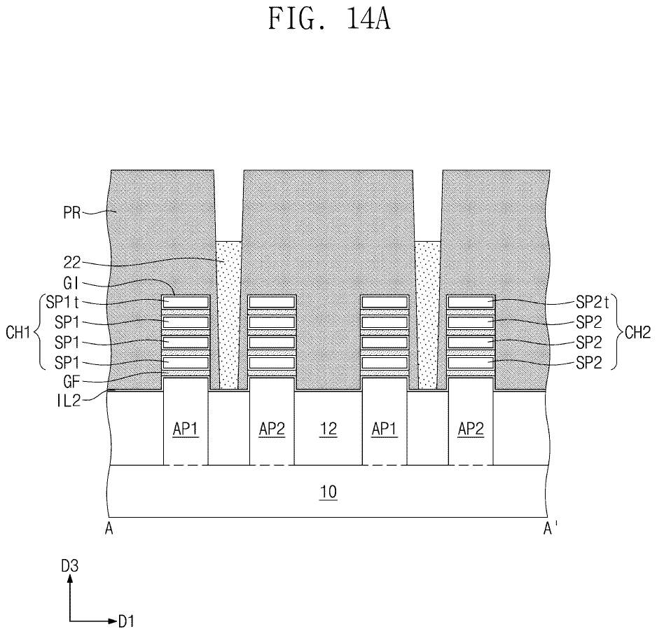

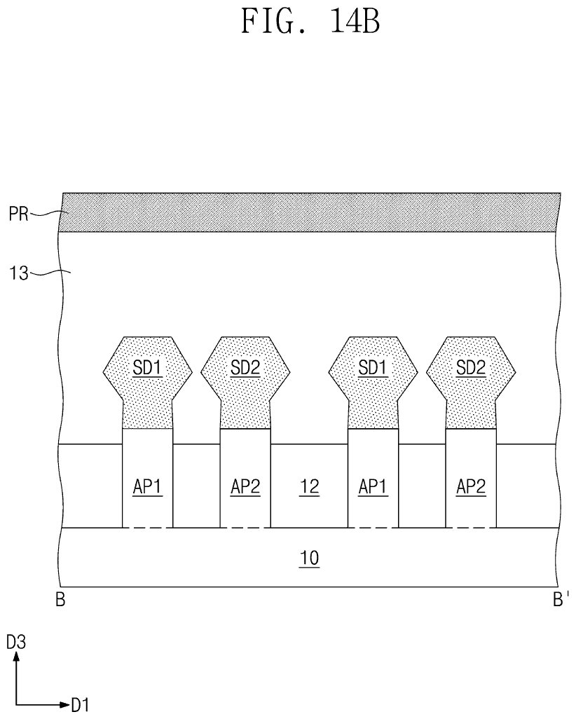

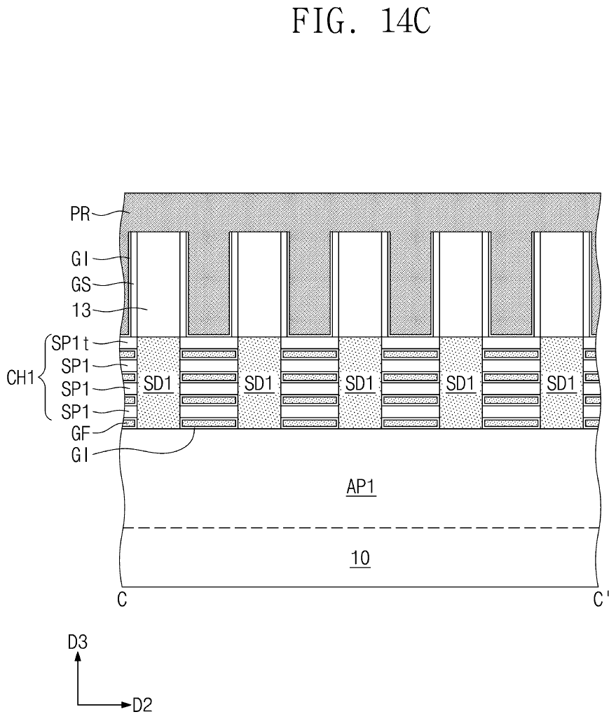

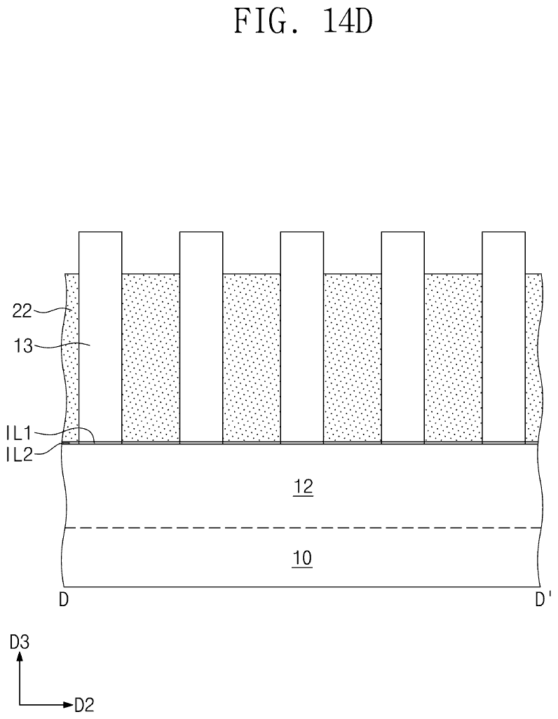

A height 25aH of the first separation structure 25a may be greater than a height 25bH of the second separation structure 25b. The height 25bH of the second separation structure 25b may be adjusted through an etching process to be described later in FIG. 14A.

The first separation structure 25a may be in contact with the gate capping pattern GP. The second separation structure 25b may be spaced apart from the gate capping pattern GP. The level of the upper surface of the gate insulating layer GI surrounding the uppermost semiconductor patterns SP1t and SP2t may be the same as that of an upper surface of the second separation structure 25b.

As the second separation structure 25b is spaced apart from the gate capping pattern GP, the first gate electrode GE1 and the second gate electrode GE2 located in a partial region of the semiconductor device may be connected to each other. That is, as the heights of the first separation structure 25a and the second separation structure 25b are different from each other, the degree of a freedom in connection and a design of the gate electrodes can be improved.

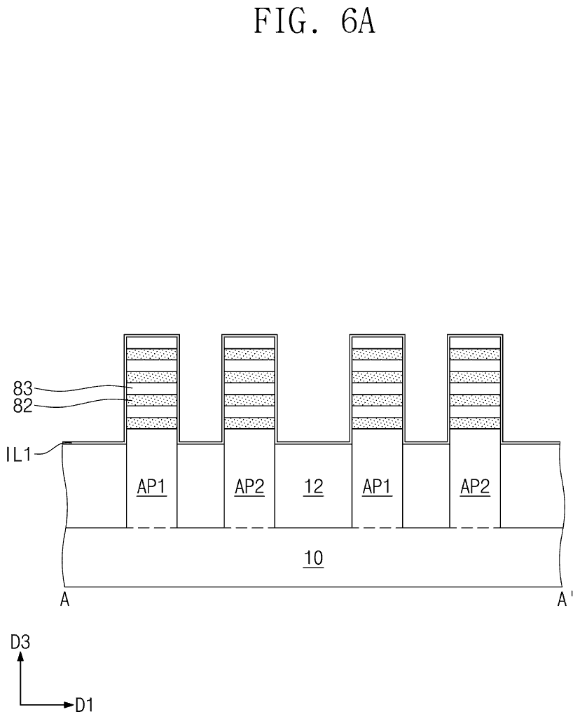

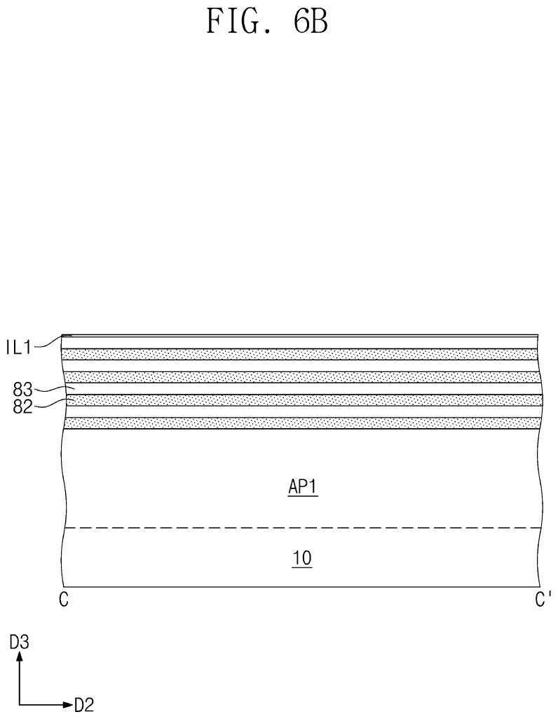

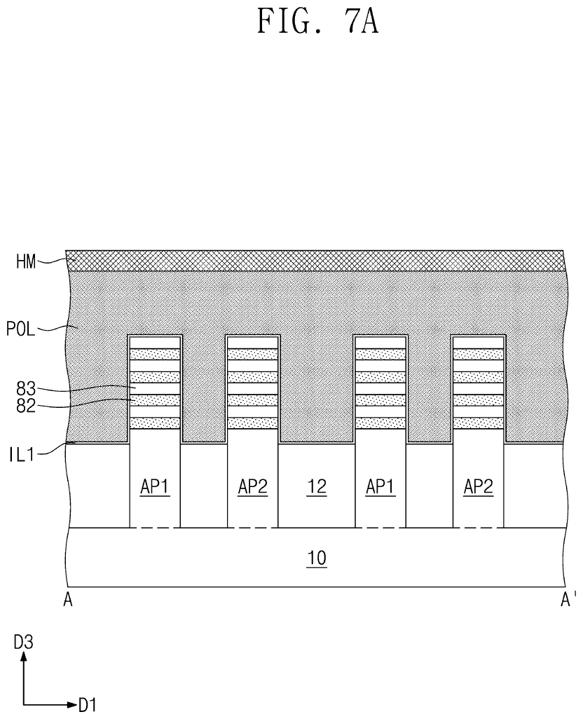

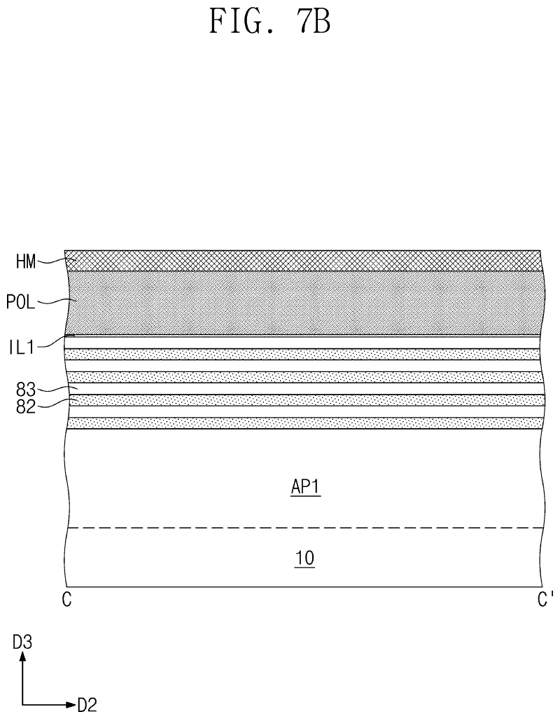

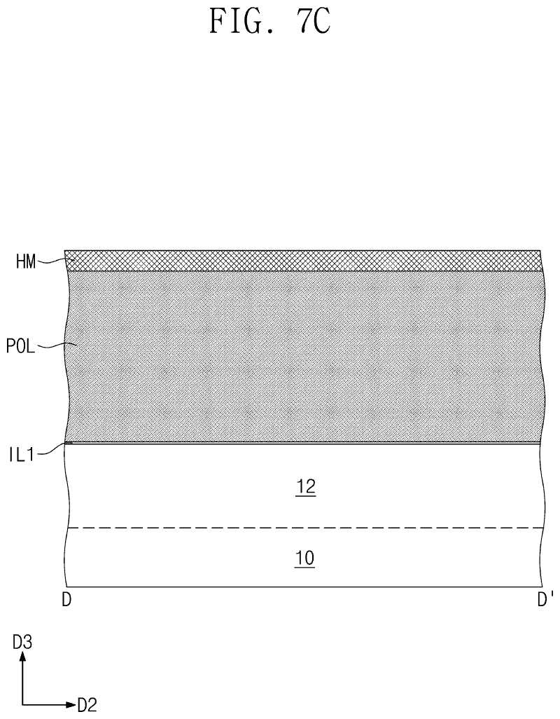

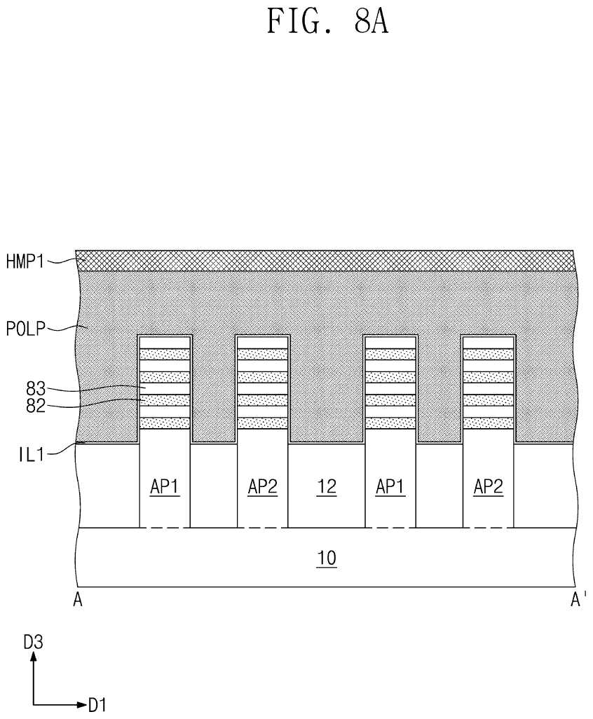

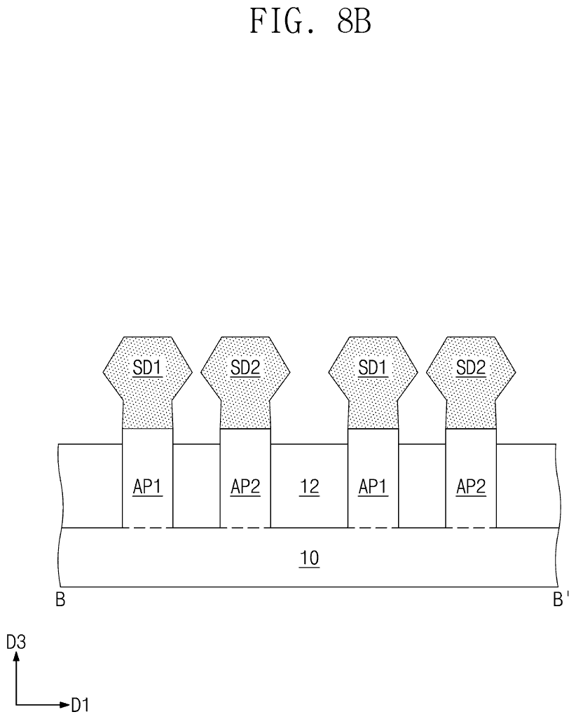

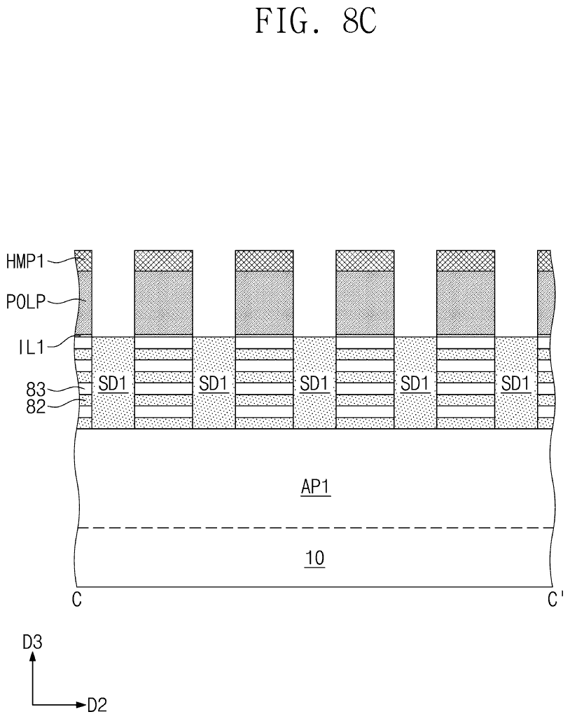

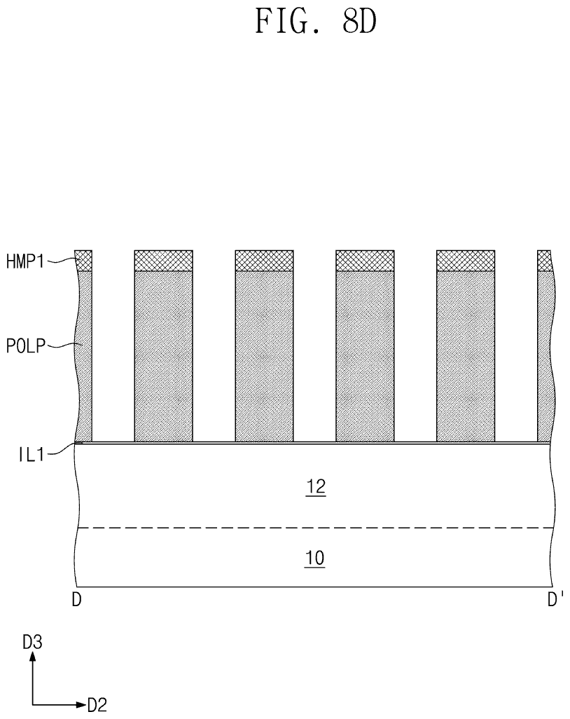

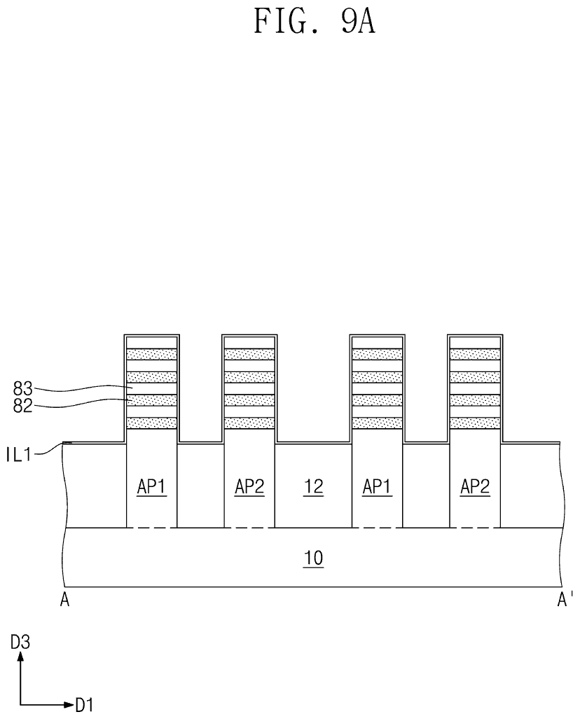

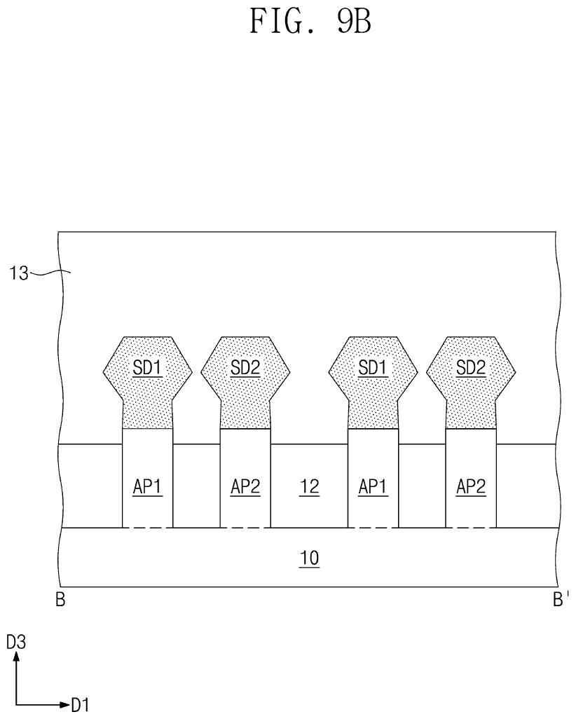

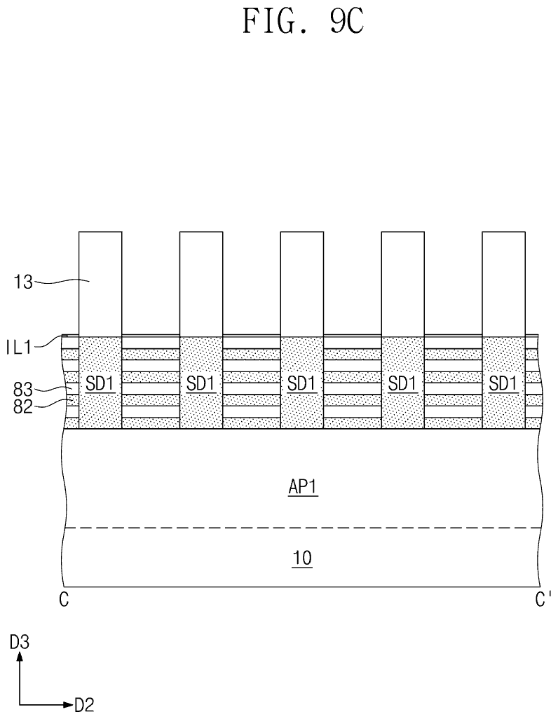

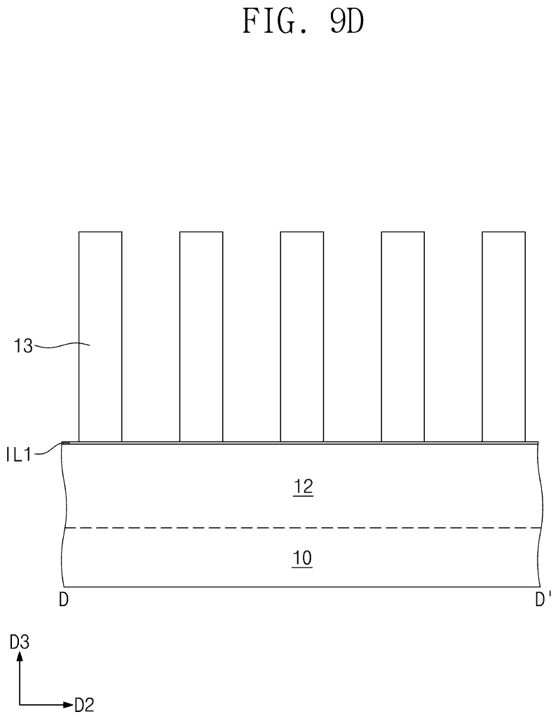

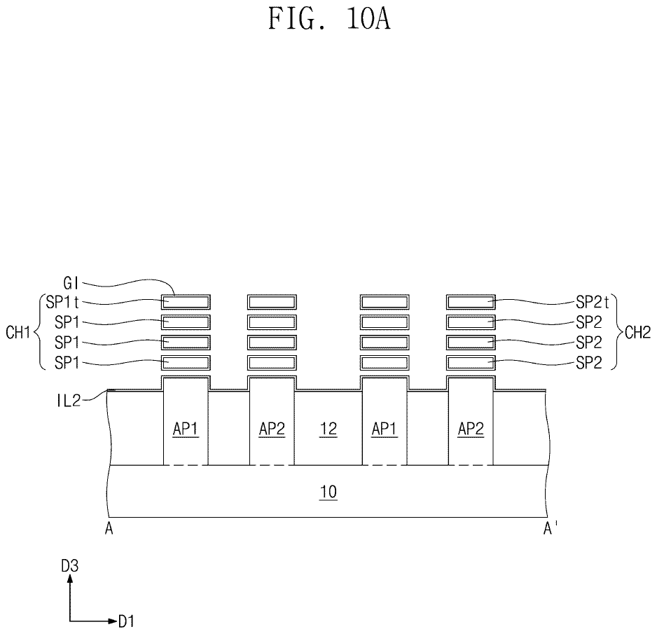

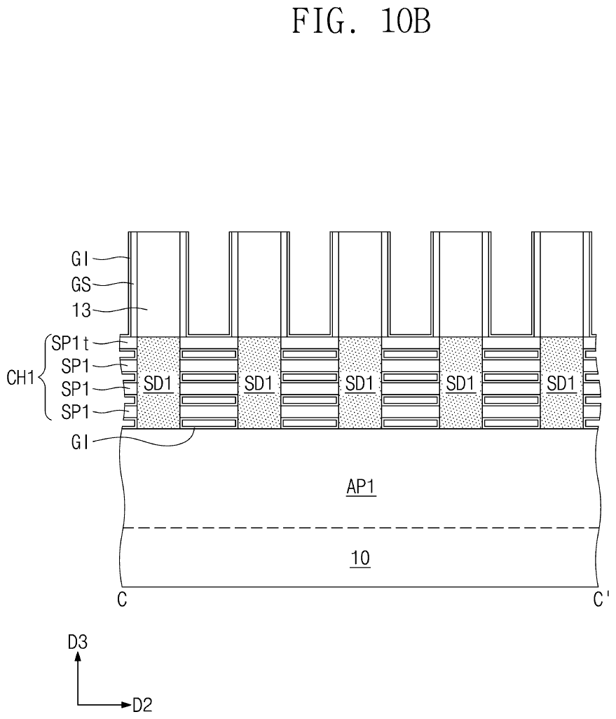

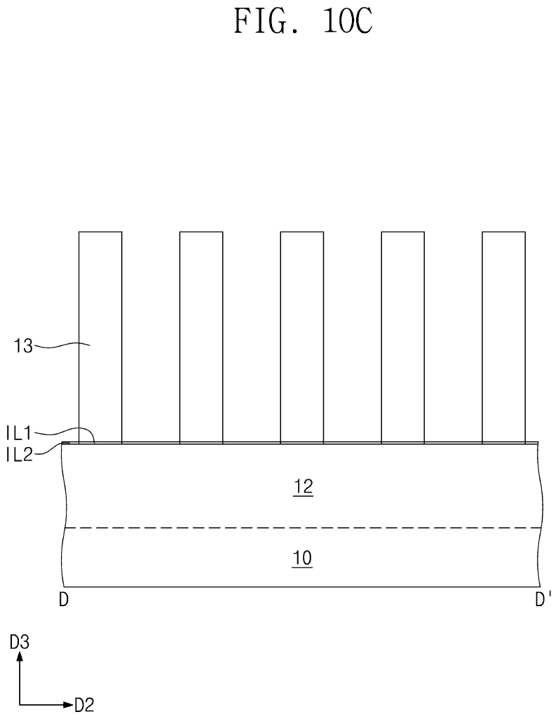

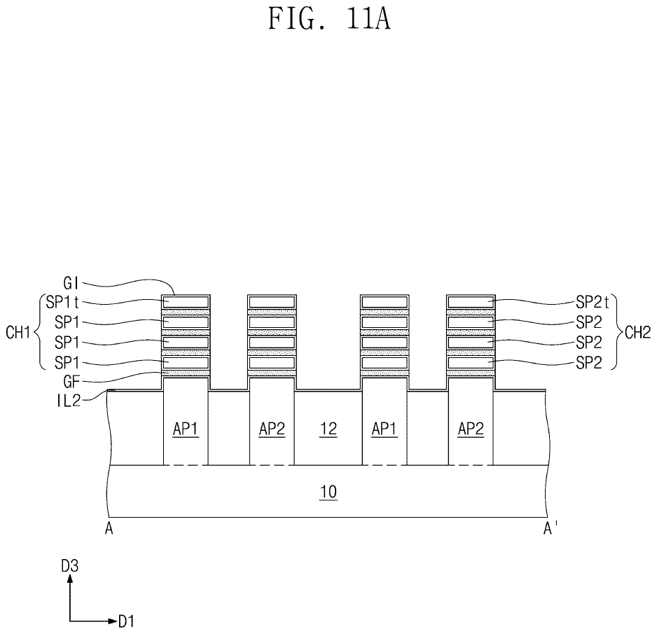

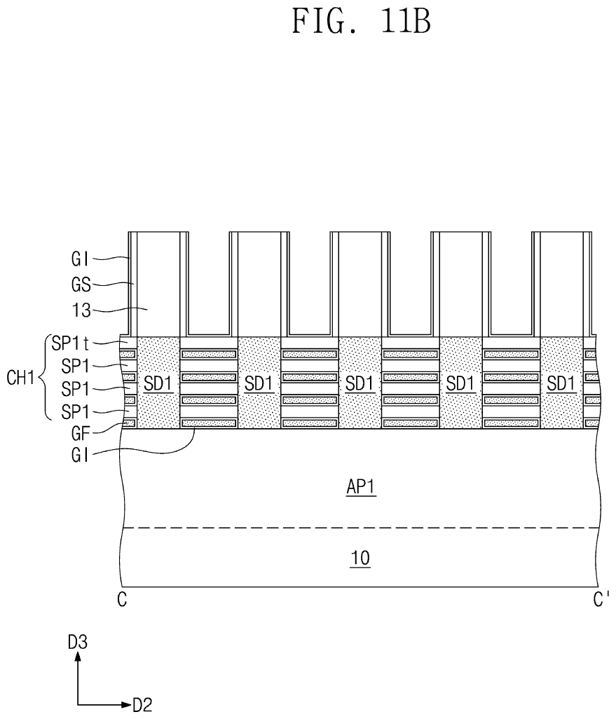

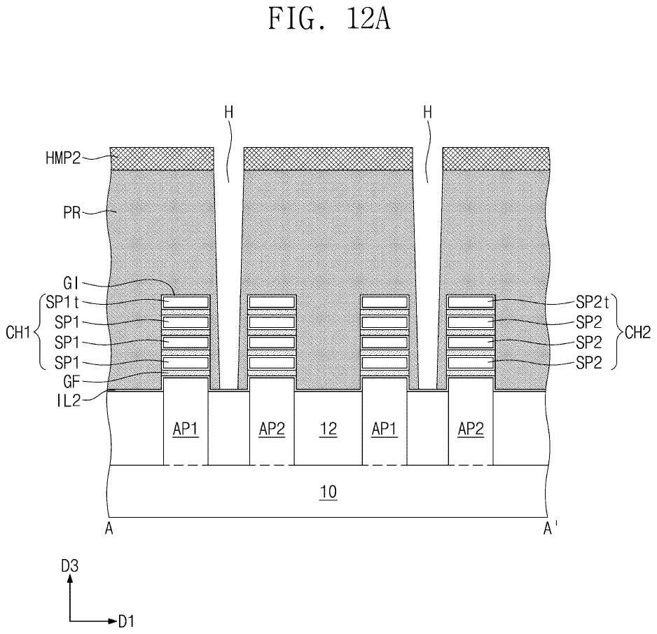

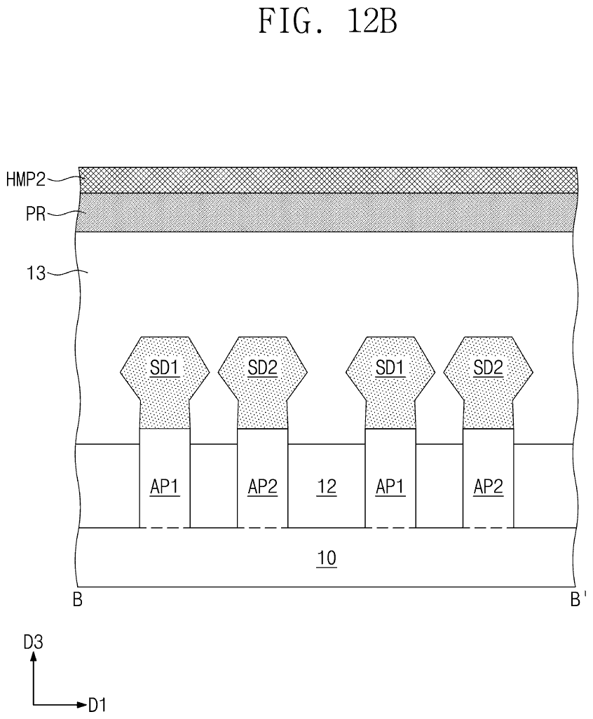

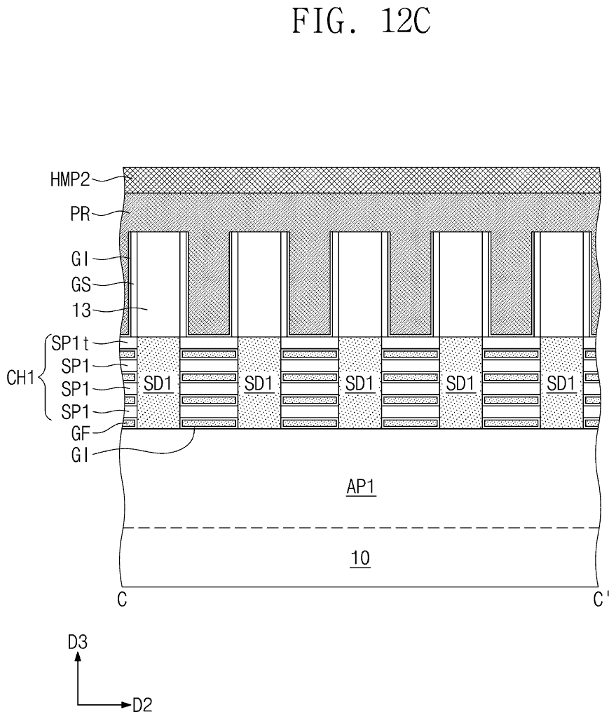

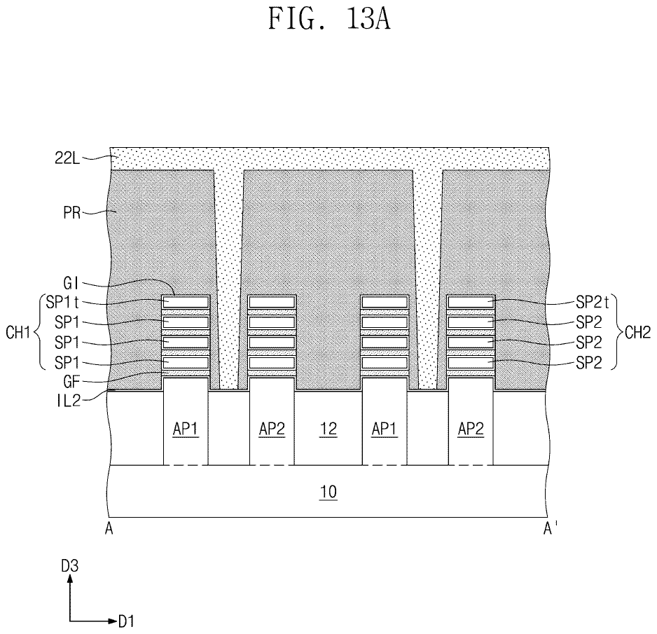

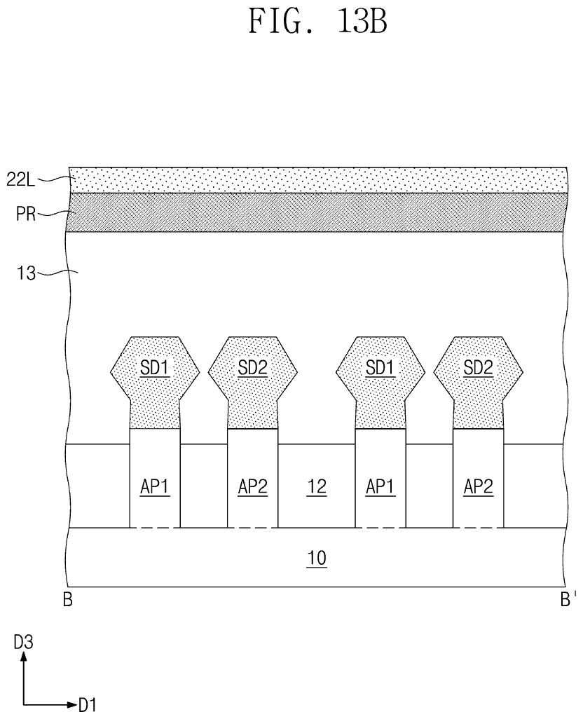

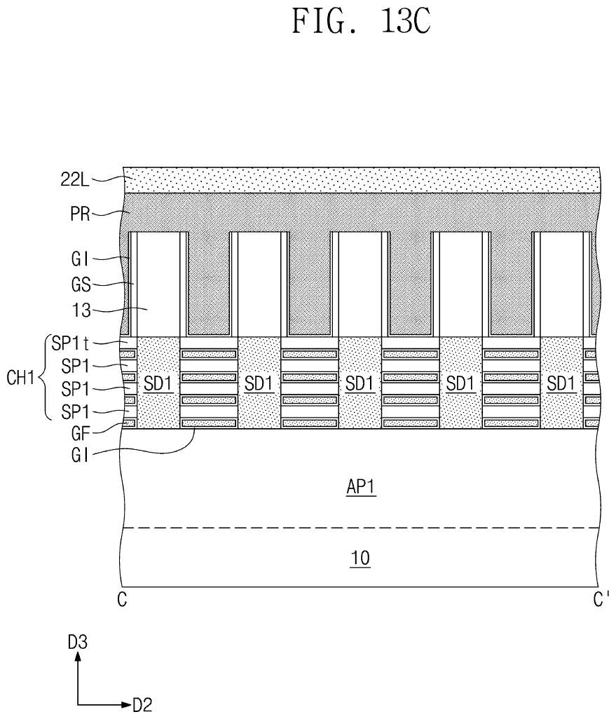

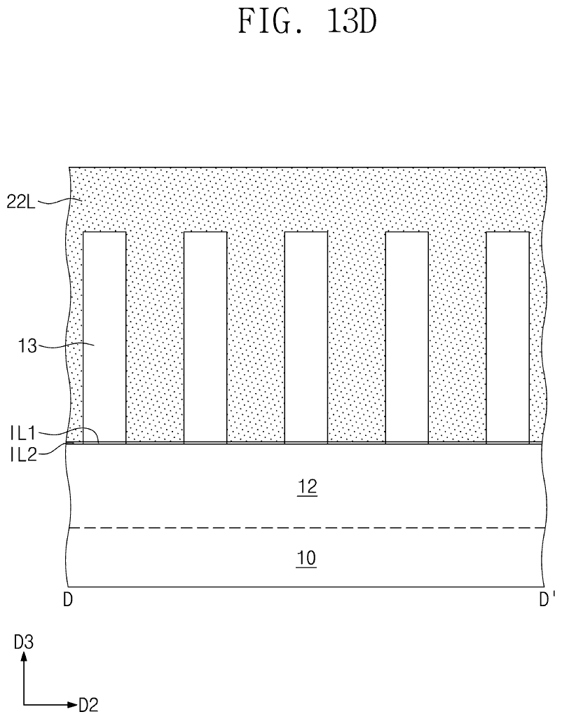

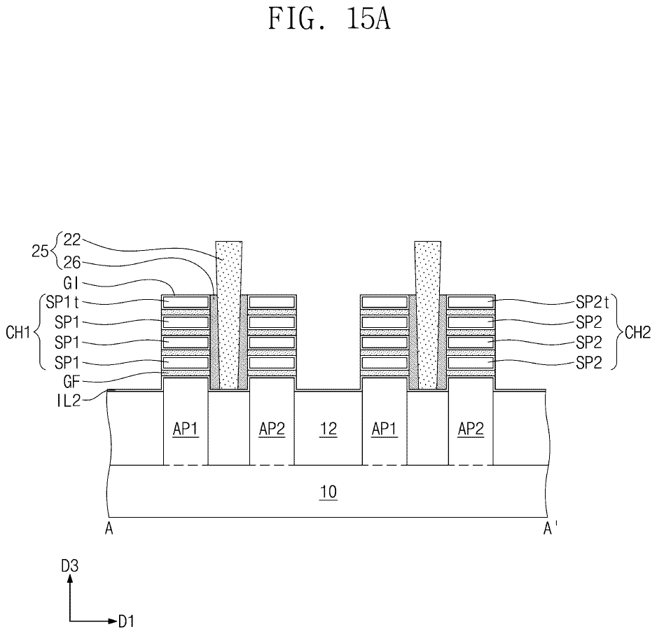

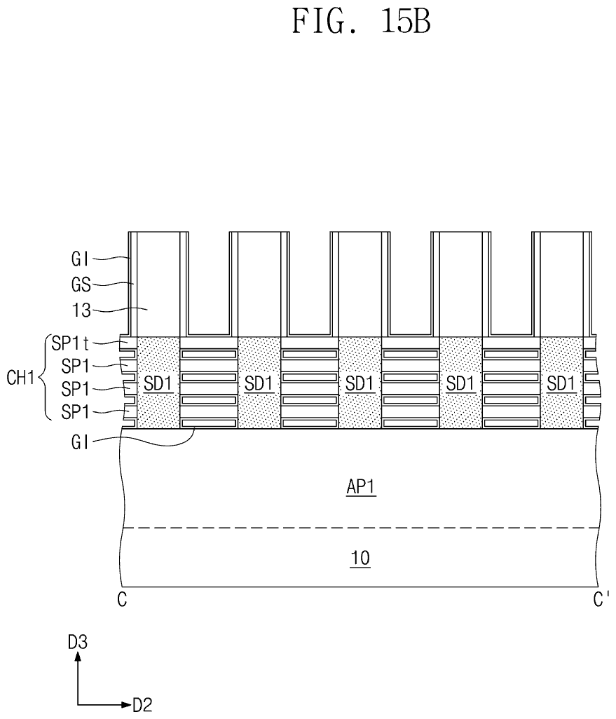

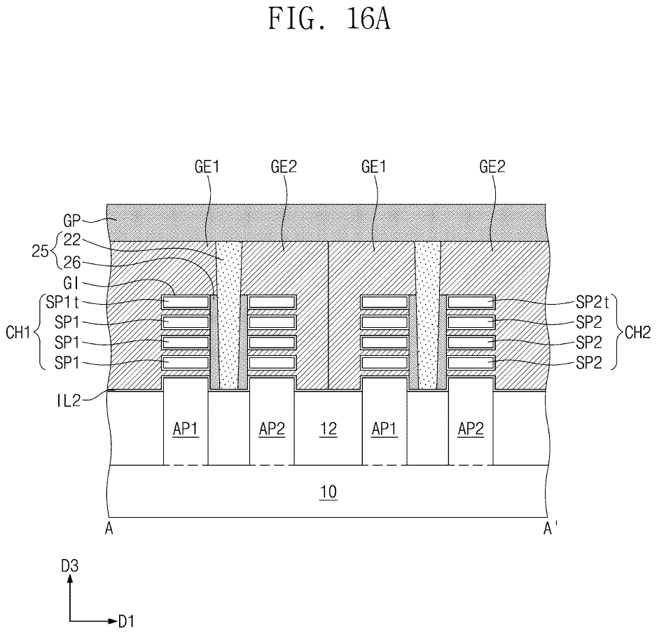

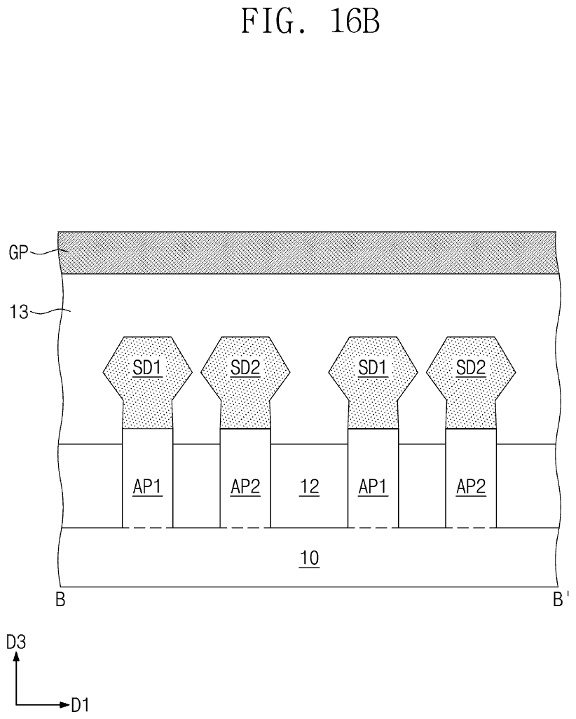

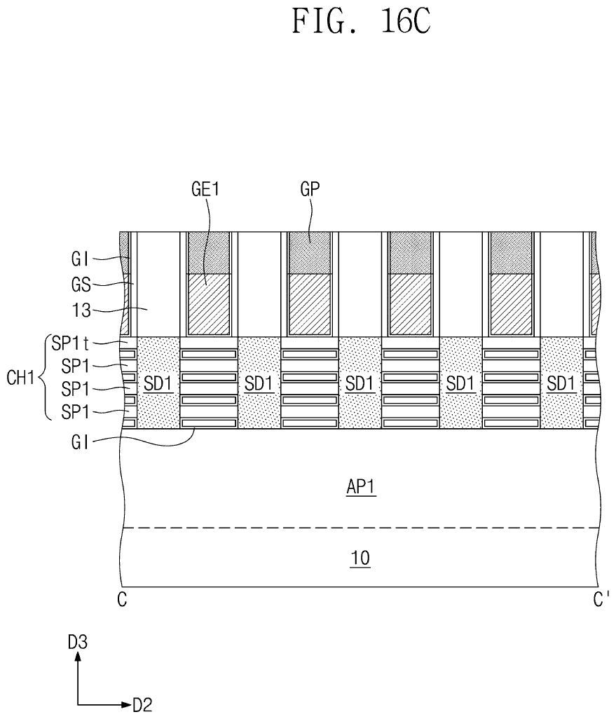

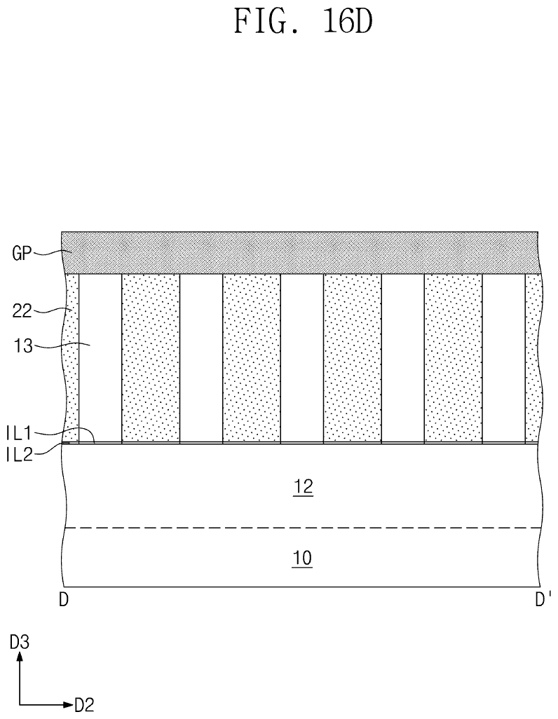

FIGS. 6A, 6B, 7A, 7B, 7C, 8A, 8B, 8C, 8D, 9A, 9B, 9C, 9D, 10A, 10B, 10C, 11A, 11B, 12A, 12B, 12C, 13A, 13B, 13C, 13D, 14A, 14B, 14C, 14D, 15A, 15B, 16A, 16B, 16C, and 16D are cross-sectional views illustrating an example of a process of fabricating a semiconductor device. Specifically, FIG. 6A, FIG. 7A, FIG. 8A, FIG. 9A, FIG. 10A, FIG. 11A, FIG. 12A, FIG. 13A, FIG. 14A, FIG. 15A, and FIG. 16A are cross-sectional views taken along line A-A′ in FIG. 1. FIGS. 8B, 9B, 12B, 13B, 14B, and 16B are cross-sectional views taken along line B-B′ of FIG. 1. FIGS. 6B, 7B, 8C, 9C, 10B, 11B, 12C, 13C, 14C, 15B, and 16C are cross-sectional views taken along line C-C′ of FIG. 1. FIGS. 7C, 8D, 9D, 10C, 13D, 14D, and 16D are cross-sectional views taken along line D-D′ of FIG. 1.

Referring to FIGS. 6A and 6B, a substrate 10 may be provided. First active pattern AP1, second active pattern AP2, first semiconductor layers 82, and second semiconductor layers 83 may be formed on the substrate 10.

Forming the first active pattern AP1, the second active pattern AP2, the first semiconductor layers 82, and the second semiconductor layers 83 may include forming preliminary semiconductor layers on the substrate 10, forming a mask pattern on the preliminary semiconductor layers, and patterning the preliminary semiconductor layers and the substrate 10 using the mask pattern.

The substrate 10 may be patterned to form the first active pattern AP1 and the second active pattern AP2. The preliminary semiconductor layers may be patterned to form the first semiconductor layers 82 and the second semiconductor layers 83. The first semiconductor layers 82 and the second semiconductor layers 83 may be alternately stacked on the substrate 10.

Each of the first semiconductor layers 82 and second semiconductor layers 83 may include a semiconductor material. The first semiconductor layers 82 and second semiconductor layers 83 may include different materials. As an example, the first semiconductor layers 82 may include silicon-germanium (SiGe), and the second semiconductor layers 83 may include silicon (Si).

Thereafter, device isolation layers 12 may be formed between the first active pattern AP1 and the second active pattern AP2. A first insulating layer IL1 may be formed on the device isolation layers 12, the first semiconductor layers 82, and the second semiconductor layers 83.

Referring to FIGS. 7A to 7C, a dummy layer POL may be formed on the first active pattern AP1, the second active pattern AP2, and the device isolation layers 12. The dummy layer POL may be extended in the second direction D2. The dummy layer POL may include, for example, polysilicon.

Then, a hard mask layer HM may be formed on the dummy layer POL. The hard mask layer HM may be extended in the second direction D2.

Referring to FIGS. 8A to 8D, a patterning process may be performed on the dummy layer POL and the hard mask layer HM. As a result of performing the patterning process, a dummy pattern POLP and a first hard mask pattern HMP1 may be formed from the dummy layer POL and the hard mask layer HM, respectively. A portion of the first semiconductor layers 82 and the second semiconductor layers 83 on the first active pattern AP1 and the second active pattern AP2 may be removed.

A First source/drain pattern SD1 and a second source/drain pattern SD2 may be formed on the region where the first semiconductor layers 82 and the second semiconductor layers 83 are removed. Forming the first source/drain pattern SD1 and the second source/drain pattern SD2 may include performing an epitaxial growth process using the active patterns AP1 and AP2 as a seed layer.

Referring to FIGS. 9A to 9D, the first hard mask pattern HMP1 may be removed. An interlayer insulating layer 13 may be formed on the first active pattern AP1, the second active pattern AP2, and the device isolation layers 12. The interlayer insulating layer 13 may cover the first source/drain pattern SD1 and the second source/drain pattern SD2. The interlayer insulating layer 13 may be formed between the dummy patterns POLP. The dummy patterns POLP may then be removed. At this time, a part of the first insulating layer IL1 exposed from the interlayer insulating layer 13 may be removed.

Referring to FIGS. 10A to 10C, the first insulating layer IL1 covering the first semiconductor layers 82 and the second semiconductor layers 83 may be removed. The first semiconductor layers 82 may then be selectively removed.

The etching process of selectively removing the first semiconductor layers 82 may remove only the first semiconductor layers 82 while remaining the second semiconductor layers 83. The etching process of removing the first semiconductor layers 82 may, for example, have a higher etch rate for silicon-germanium. Due to the etching process, a first channel structures CH1 including the first semiconductor patterns SP1 and SP1t and a second channel structures CH2 including the second semiconductor patterns SP2 and SP2t may be formed from the second semiconductor layers 83. The first channel structures CH1 and the second channel structures CH2 may be spaced apart from each other in the first direction D1.

Thereafter, a gate spacer GS may be formed on the uppermost semiconductor patterns SP1t and SP2t. The second insulating layer IL2 may be formed on the device isolation layers 12. The second insulating layer IL2 may cover the upper surfaces of the first active pattern AP1 and the second active pattern AP2. A gate insulating layer GI may be formed on the first semiconductor patterns SP1 and the second semiconductor patterns SP2. The gate insulating layer GI may be formed to surround the four surfaces of each of the first semiconductor patterns SP1 and the second semiconductor patterns SP2.

Referring to FIGS. 11A and 11B, an inner gap-fill layer GF may be formed on the first semiconductor patterns SP1 and the second semiconductor patterns SP2 adjacent to each other in the third direction D3. Forming the inner gap-fill layer GF may include, for example, forming the inner gap-fill layer GF on the device isolation layers 12 and patterning a portion of the inner gap-fill layer GF.

Referring to FIGS. 12A to 12C, a photoresist pattern PR and a second hard mask pattern HMP2 may be formed on the device isolation layers 12. The second hard mask pattern HMP2 may be formed on the photoresist pattern PR.

Then, an etching process may be performed on the photoresist pattern PR and the second hard mask pattern HMP2. As a result of performing the etching process, a plurality of holes H may be formed. The holes H may be extended in the third direction D3. The etching process may be performed, for example, until an upper surface of the second insulating layer IL2 is exposed.

Referring to FIGS. 13A to 13D, the second hard mask pattern HM2 may be removed. The preliminary core structure 22L may then fill the holes H in a self-aligned manner. In this specification, the preliminary core structure 22L filling the holes H may be expressed in the same manner as the insulating material filling the holes H. The preliminary core structure 22L may fill between the interlayer insulating layers 13 and cover an upper surface of the photoresist pattern PR.

The preliminary core structure 22L may include, for example, an insulating material. As an example, the preliminary core structure 22L may include at least one of silicon oxide, silicon nitride, or silicon carbonitride.

Referring to FIGS. 14A to 14D, an etching process may be performed on the preliminary core structure 22L. Due to the etching process, an upper portion of the preliminary core structure 22L may be removed, including a portion covering the upper surface of the photoresist pattern PR.

At this time, the level of the upper surface of the preliminary core structure 22L can be adjusted through an etching process. As an example, etching the upper portion of the preliminary core structure 22L may be performed until the level of the upper surface of the preliminary core structure 22L is equal to or higher than that of the upper surfaces of the uppermost semiconductor patterns SP1t and SP2t. Since the level of the upper surface of the preliminary core structure 22L is adjusted through such etching process, the heights of the first gate electrode GE1 and the second gate electrode GE2 can be adjusted. As a result of performing the etching process, the core structure 22 may be formed from the preliminary core structure 22L. As the core structure 22 is formed after the semiconductor patterns SP1 and SP2 and the gate insulating layer GI are formed, the semiconductor patterns SP1 and SP2 may be prevented from being damaged.

Referring to FIGS. 15A and 15B, the photoresist pattern PR may be removed. A cladding structure 26 surrounding the core structure 22 may then be formed in a self-aligned manner. Forming the cladding structure 26 may include forming a cladding layer on the device isolation layers 12 and performing a patterning process on the cladding layer.

As a result of performing the patterning process, portions of the cladding layer, except for those formed between the first channel structures CH1 and the second channel structures CH2, may be removed. A level of an upper surface of the cladding structure 26 may be the same as that of the upper surface of the gate insulating layer GI surrounding the uppermost semiconductor patterns SP1t and SP2t.

As the cladding structure 26 is formed, a separation structure 25 including the core structure 22 and the cladding structure 26 may be formed. Thereafter, the inner gap-fill layer GF may be removed.

Referring to FIGS. 16A to 16D, a planarization process may be performed on the interlayer insulating layer 13. Then, a first gate electrode GE1 and a second gate electrode GE2 may be formed on the gate insulating layer GI. As an example, the first gate electrode GE1 may be formed on the first semiconductor patterns SP1. The second gate electrode GE2 may be formed on the second semiconductor patterns SP2. Forming the first gate electrode GE1 and the second gate electrode GE2 may include forming the first gate electrode GE1 and the second gate electrode GE2 until the level of an upper surface of the first gate electrode GE1 and the level of an upper surface of the second gate electrode GE2 are equal to the level of an upper surface of the separation structure 25. That is, as the heights of the first and second gate electrodes GE1 and GE2 are formed equal to the height of the separation structure 25, a step difference between the two components may be prevented. A gate capping pattern GP covering the first gate electrode GE1 and the second gate electrode GE2 may be formed.

Then, referring again to FIGS. 2A to 2D, by forming the gate contacts 45 penetrating the gate capping pattern GP and the active contacts 41 penetrating the interlayer insulating layer 13, a semiconductor device can be completed.

A semiconductor device may include a separation structure between a plurality of semiconductor patterns and separating gate electrodes at a higher level than the semiconductor patterns. At this time, a portion of a side surface of the separation structure may be exposed from the gate insulating layer to be in contact with the gate electrodes. Since the gate electrodes are provided closer to the separation structure than a side surface of the semiconductor patterns, the area provided for the gate electrodes can be increased. As a result, the control capability for the semiconductor patterns of the gate electrodes can be further improved.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While implementations are described above, a person skilled in the art may understand that many modifications and variations are made without departing from the spirit and scope of the present disclosure defined in the following claims. Accordingly, the example implementations should be considered in all respects as illustrative and not restrictive, with the spirit and scope of the present disclosure being indicated by the appended claims.

What is claimed is:

1. A semiconductor device comprising:
an active pattern on a substrate;
a first channel structure and a second channel structure spaced apart from each other on the active pattern;
a gate electrode on the first channel structure and the second channel structure; and
a separation structure between the first channel structure and the second channel structure,
wherein the first channel structure includes a first plurality of semiconductor patterns and the second channel structure includes a second plurality of semiconductor patterns,
wherein an upper surface of the separation structure is higher than an upper surface of an uppermost semiconductor pattern among the first plurality of semiconductor patterns and the second plurality of semiconductor patterns, and
wherein the gate electrode contacts the separation structure.

2. The semiconductor device of claim 1, wherein the separation structure includes at least one of silicon oxide, silicon nitride, or silicon carbonitride.

3. The semiconductor device of claim 1, wherein the separation structure comprises a core structure and a cladding structure surrounding the core structure, and
wherein an upper surface of the core structure is higher than an upper surface of the cladding structure.

4. The semiconductor device of claim 3, wherein:
the core structure has a first width in a first direction parallel to an upper surface of the substrate,
the cladding structure has a second width in the first direction, and
the second width is smaller than the first width.

5. The semiconductor device of claim 4, wherein the first width is between 10 nm and 40 nm, and the second width is between 2 nm and 10 nm.

6. The semiconductor device of claim 3, wherein the core structure comprises a first portion and a second portion on the first portion,
wherein the second portion protrudes from the cladding structure, and
wherein a height of the second portion is 10% to 45% of a height of the core structure.

7. The semiconductor device of claim 6, wherein the height of the second portion is 5 nm to 40 nm.

8. The semiconductor device of claim 1, comprising source/drain patterns connected to the first channel structure and the second channel structure, and
wherein the separation structure is spaced apart from the source/drain patterns.

9. A semiconductor device comprising:
a substrate comprising an active pattern;
a device isolation layer defining the active pattern;
a first channel structure and a second channel structure spaced apart from each other on the active pattern;
a gate electrode on the first channel structure and the second channel structure;
a gate insulating layer between the gate electrode and the first channel structure and between the gate electrode and the second channel structure; and
a separation structure between the first channel structure and the second channel structure,
wherein the first channel structure includes a first plurality of semiconductor patterns having four surfaces and the second channel structure includes a second plurality of semiconductor patterns having four surfaces,
wherein an upper surface of the separation structure is higher than an upper surface of a n uppermost semiconductor pattern among the first plurality of semiconductor patterns and the second plurality of semiconductor patterns,
wherein the gate insulating layer surrounds the four surfaces of each semiconductor pattern of the first plurality of semiconductor patterns and the second plurality of semiconductor patterns, and
wherein a portion of side surface of the separation structure is exposed from the gate insulating layer.

10. The semiconductor device of claim 9, wherein a portion of the gate insulating layer contacts the separation structure, and
wherein the portion of the gate insulating layer contacting with the separation structure overlaps with the gate electrode in a vertical perspective.

11. The semiconductor device of claim 9, wherein the separation structure comprises a plurality of indent regions, and
wherein the gate electrode is provided at each indent region of the plurality of indent regions.

12. The semiconductor device of claim 11, wherein a width of each indent region of the plurality of indent regions is 2 nm to 10 nm.

13. The semiconductor device of claim 9, wherein the separation structure comprises a core structure and a cladding structure surrounding the core structure, and
wherein the cladding structure is between the gate insulating layer and the core structure and between the gate electrode and the core structure in a horizontal perspective.

14. The semiconductor device of claim 13, wherein an upper surface of the gate insulating layer surrounding the uppermost semiconductor pattern is the same as an upper surface of the cladding structure.

15. A semiconductor device comprising:
a substrate comprising a first active pattern and a second active pattern, the first active pattern and the second active pattern being defined by a device isolation layer;
a first channel structure on the first active pattern and a second channel structure on the second active pattern;
source/drain patterns connected to the first channel structure and the second channel structure;
a first gate electrode on the first channel structure and a second gate electrode on the second channel structure;
a gate insulating layer between the first gate electrode and the first channel structure and between the second gate electrode and the second channel structure; and
a separation structure between the first channel structure and the second channel structure,
wherein the first channel structure includes a first plurality of semiconductor patterns having four surfaces and the second channel structure includes a second plurality of semiconductor patterns having four surfaces,
wherein the gate insulating layer surrounds the four surfaces of each semiconductor pattern of the first plurality of semiconductor patterns and the second plurality of semiconductor patterns,
wherein an upper surface of the separation structure is higher than an upper surface of an uppermost semiconductor pattern among the first plurality of semiconductor patterns and the second plurality of semiconductor patterns, and
wherein a portion of a side surface of the separation structure contacts the gate insulating layer, and the rest of the side surface of the separation structure contacts the first gate electrode and the second gate electrode in a horizontal point of view.

16. The semiconductor device of claim 15, wherein the separation structure includes a first separation structure and a second separation structure spaced apart from each other, and
wherein a height of the first separation structure is greater than a height of the second separation structure.

17. The semiconductor device of claim 16, comprising a gate capping pattern covering the first gate electrode and the second gate electrode,
wherein the first separation structure contacts the gate capping pattern, and
wherein the second separation structure is spaced apart from the gate capping pattern.

18. The semiconductor device of claim 16, wherein an upper surface of the gate insulating layer surrounding the uppermost semiconductor pattern is the same as an upper surface of the second separation structure.

19. The semiconductor device of claim 15, wherein the first gate electrode and the second gate electrode are closer to the separation structure than to a side surface of the first plurality of semiconductor patterns and a side surface of the second plurality of semiconductor patterns.

20. The semiconductor device of claim 15, wherein an end of the gate insulating layer is aligned with an end of the first gate electrode and an end of the second gate electrode with respect to a line extending in a vertical direction.
